(19) United States
(12) Patent Application Publication
(10) Pub. No.: US 2004/0239373 A1
(43) Pub. Date: Dec. 2, 2004

(54) Semiconductor laser driving circuit and optical communication apparatus

(75) Inventor: Toshiki Seshita, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/779,630

(22) Filed: Feb. 18, 2004

(30) Foreign Application Priority Data
May 28, 2003 (JP) 2003-151390

(51) Int. Cl. H03K 5/22

(52) U.S. Cl. 327/65

(57) ABSTRACT

According to the present invention, there is provided a semiconductor laser driving circuit including a differential output unit which performs differential amplification by receiving complementary input signals, and outputs complementary signals from first and second output terminals, having:

an RC filter with a switch obtained by connecting, between the first and second output terminals, two ends of a switching element, two ends of at least one resistor, and two ends of at least one capacitor in series;

two resistors connected in series between a high-potential power supply terminal and the first output terminal;

a high-pass filter or bandpass filter which receives an output from a connecting point between the two resistors, and passes a component not lower than a predetermined frequency;

a detection rectifier which receives a signal passed through the high-pass filter or bandpass filter, converts the received signal into a DC component or low-frequency component, and outputs the DC component or low-frequency component; and

a hysteresis comparator which receives an output from the detection rectifier, outputs an ON signal if the received output exceeds a high-potential threshold value, and keeps outputting the ON signal unless the output from the detection rectifier becomes lower than a low-potential threshold value,

wherein the switching element is turned on and the RC filter with the switch starts operating accordingly when the output ON signal from the hysteresis comparator is supplied to the switching element.

### CROSS REFERENCE TO RELATED APPLICATION

This application is based upon and claims benefit of priority under 35 USC 119 from the Japanese Patent Application No. 2003-151390, filed on May 28, 2003, the entire contents of which are incorporated herein by reference.

### BACKGROUND OF THE INVENTION

The present invention relates to a semiconductor laser driving circuit and an optical communication apparatus using the same.

FIG. 5 shows the arrangement of a conventional optical transmitter for driving a semiconductor laser by using a semiconductor laser driving circuit.

A semiconductor laser driving circuit 103 has a driver stage DS, differential output unit 102, and driving current controller 101. In addition to the semiconductor laser driving circuit 103, the optical transmitter further includes a terminal resistor TR, RC filter circuit RCF, laser diode LD1, choke coil CC1, and current source CS1.

Differential input signals IN+ and IN− are input to the driver stage DS, and then input to the bases of bipolar transistors Q111 and Q112, respectively, of the differential output unit 102. The differential output unit 102 operates when a bias electric current is supplied from the driving current controller 101 to the base of a transistor Q113. Consequently, differential output signals OUT+ and OUT− corresponding to the differential input signals supplied to the bases of the transistors Q111 and Q112 are extracted from collectors.

The laser diode LD1 which is driven by an electric current is a single-phase-input diode, and is driven by the signal OUT− as one differential output signal from the semiconductor laser driving circuit 103. The other signal OUT+ is terminated by the terminal resistor TR connected outside the semiconductor laser driving circuit 103.

The polarities of the differential input signals IN+ and IN− and the signal OUT− for driving the laser diode LD1 are as follows. That is, when the input signal IN+ is at high level, the driving signal OUT− changes to low level, and a driving current flows. Therefore, not the signal OUT+ but the signal OUT− of the output signals is used to drive the laser diode LD1.

The impedances of high-frequency transmission lines are normally standardized at 50 Ω, so matching must be obtained at this value. Since, however, the ON resistance of the laser diode LD1 is as low as a few Ω, a resistor Rd is generally inserted in series. If the resistor Rd is not inserted, a reflected wave is generated by impedance mismatching, and the waveform of the driving signal deteriorates.

Unfortunately, it is impossible, by only inserting the resistor Rd, to suppress overshoot, undershoot, and ringing caused by a parasitic inductance and parasitic capacitance present in the laser diode LD1, bonding wires, and the like.

Accordingly, waveform deterioration is suppressed by inserting the RC filter circuit RCF including a capacitor C1 and resistor R121 between the semiconductor laser driving circuit 103 and laser diode LD1. In this case, it is of course necessary to optimize parameters of the RC filter circuit RCF.

If the RC filter circuit RCF is not properly designed, no waveform shaping effect can be obtained. Alternatively, suppression of waveform deterioration becomes too strong to obtain sharp edges, so specifications concerning a leading edge tr and trailing edge tf of the waveform are not satisfied any longer.

This waveform deterioration problem becomes conspicuous if a non-cooling laser diode is used, for the reason explained below.

A laser diode strongly depends upon temperature, and decreases its light emission efficiency if the temperature rises. To compensate for this decrease in emission efficiency, therefore, the driving current is supplied as it is controlled in accordance with the temperature. That is, the driving current is increased when the temperature rises.

Unfortunately, if the driving current changes and the output amplitude changes accordingly, the degree of waveform deterioration caused by overshoot, undershoot, and ringing changes in many cases.

Accordingly, even when the RC filter circuit RCF is formed outside the semiconductor laser driving circuit 103, the characteristics of the RC filter circuit RCF are optimized only at a specific temperature, and are not optimized at other temperatures. Consequently, the waveform shaping effect is unsatisfactory, or suppression of waveform deterioration is too strong, and this deteriorates the waveform.

References disclosing conventional semiconductor laser driving circuits are as follows.

Japanese Patent Laid-Open No. 2003-78200

Japanese Patent Laid-Open No. 7-162290

In the conventional optical communication apparatus as described above, the characteristics of the RC filter circuit RCF cannot follow changes in temperature and hence are not optimized. This deteriorates the output waveform of the driving current.

### SUMMARY OF THE INVENTION

According to one aspect of the present invention, there is provide a semiconductor laser driving circuit including a differential output unit which performs differential amplification by receiving complementary input signals, and outputs complementary signals from first and second output terminals, comprising:

an RC filter with a switch obtained by connecting, between said first and second output terminals, two ends of a switching element, two ends of at least one resistor, and two ends of at least one capacitor in series;

two resistors connected in series between a high-potential power supply terminal and said first output terminal;

a high-pass filter or bandpass filter which receives an output from a connecting point between said two resistors, and passes a component not lower than a predetermined frequency;

a detection rectifier which receives a signal passed through said high-pass filter or bandpass filter, converts the received signal into a DC component or low-frequency component, and outputs the DC component or low-frequency component; and

a hysteresis comparator which receives an output from said detection rectifier, outputs an ON signal if the received output exceeds a high-potential threshold value, and keeps outputting the ON signal unless the output from said detection rectifier becomes lower than a low-potential threshold value,

wherein said switching element is turned on and said RC filter with said switch starts operating accordingly when the output ON signal from said hysteresis comparator is supplied to said switching element.

According to one aspect of the present invention, there is provided an optical communication apparatus comprising:

said semiconductor laser driving circuit; and

a laser diode which receives an output signal from a first or second output terminal of said semiconductor laser driving circuit.

According to one aspect of the present invention, there is provided an semiconductor laser driving circuit including a differential output unit which performs differential amplification by receiving complementary input signals, and outputs complementary signals from first and second output terminals, comprising:

first, second, . . . , nth (n is an integer not less than 2) RC filters with switches each of which is obtained by connecting, between said first and second output terminals, two ends of a switching element, two ends of at least one resistor, and two ends of at least one capacitor in series, and which are connected to each other in parallel;

first, second, . . . , nth resistor units each of which includes two resistors connected in series between a high-potential power supply terminal and said first output terminal, and which are connected to each other in parallel;

first, second, . . . , nth bandpass filters each of which receives an output from a connecting point between said two resistors included in a corresponding one of said first, second, . . . , nth resistor units, and passes a component not lower than a predetermined frequency;

first, second, . . . , nth detection rectifiers each of which receives a signal passed through a corresponding one of said first, second, . . . , nth bandpass filters, converts the received signal into a DC component or low-frequency component, and outputs the DC component or low-frequency component; and

first, second, . . . , nth hysteresis comparators each of which receives an output from a corresponding one of said first, second, . . . , nth detection rectifiers, outputs an ON signal if the received output exceeds a high-potential threshold value, and keeps outputting the ON signal unless the output from said detection rectifier becomes lower than a low-potential threshold value,

wherein said switching element included in each of said first, second, . . . , nth RC filters with said switches is turned on when the output ON signal from a corresponding one of said first, second, . . . , nth hysteresis comparators is supplied, and a corresponding one of said first, second, . . . , nth RC filters with said switches starts operating accordingly.

### BRIEF DESCRIPTION OF THE DRAWINGS

FIG. 1 is a circuit diagram showing the arrangement of a semiconductor laser driving circuit according to the first embodiment of the present invention;

FIG. 2 is a graph comparing the output driving current from the semiconductor laser driving circuit according to the first embodiment with the output driving current from a conventional semiconductor laser driving circuit;

FIG. 3 is a circuit diagram showing the arrangement of a semiconductor laser driving circuit according to the second embodiment of the present invention;

FIG. 4 is a circuit diagram showing a modification of the semiconductor laser driving circuit according to the first embodiment; and

FIG. 5 is a circuit diagram showing the arrangement of an optical transmitter using the conventional semiconductor laser driving circuit.

### DESCRIPTION OF THE PREFERRED EMBODIMENTS

Embodiments of the present invention will be described below with reference to the accompanying drawings.

(1) First Embodiment

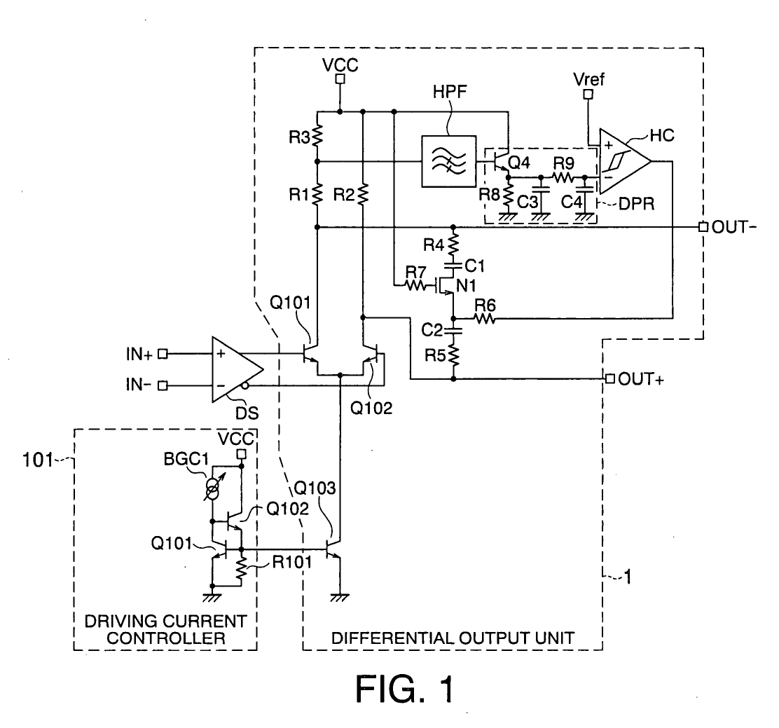

FIG. 1 shows the arrangement of a semiconductor laser driving circuit according to the first embodiment of the present invention.

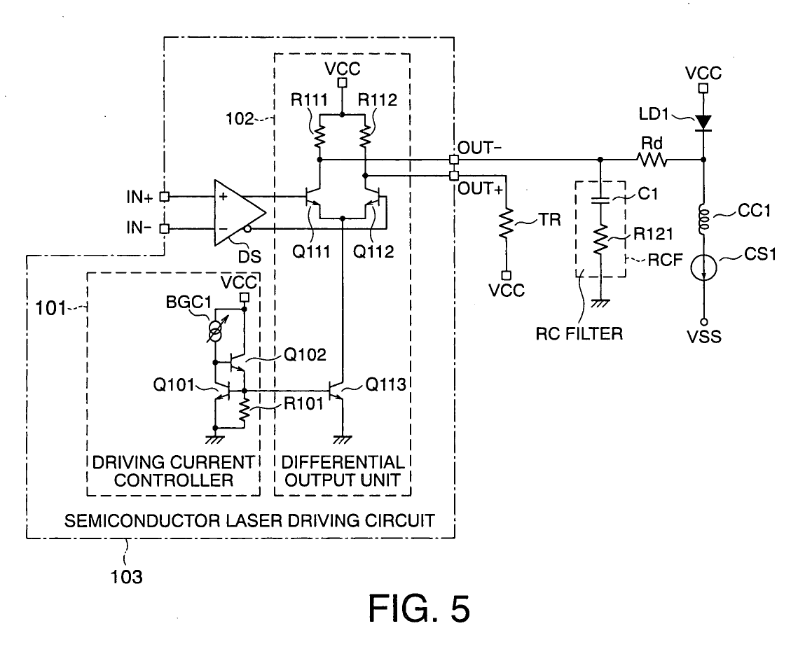

An optical communication apparatus according to this embodiment is obtained by replacing the semiconductor laser driving circuit 103 included in the optical communication apparatus shown in FIG. 5 with the semiconductor laser driving circuit shown in FIG. 1.

The semiconductor laser driving circuit according to this embodiment includes a driver stage DS, driving current controller 101, and differential output unit 1. A difference from the semiconductor laser driving circuit 103 shown in FIG. 5 is the arrangement of the differential output unit 1.

In the differential output unit 1 included in this embodiment, resistors R3 and R1 are connected in series between the collector of a transistor Q101 having a base connected to one differential output terminal of the driver stage DS, and a power supply voltage VCC terminal. A resistor R2 is connected between the collector of a transistor Q102 having a base connected to the other differential output terminal of the driver stage DS, and the power supply voltage VCC terminal.

The collectors of the transistors Q101 and Q102 are connected to differential output terminals OUT− and OUT+, respectively, of the differential output unit 1. Between the differential output terminals OUT− and OUT+, a resistor R4, a capacitor C1, the drain and source of an N-channel MOS transistor N1, a capacitor C2, and a resistor R5 are connected in series, thereby forming an RC filter with a switch.

The gate of the transistor N1 is connected to the power supply voltage VCC terminal via a resistor R7. The source of the transistor N1 is connected to the output terminal of a hysteresis comparator HC (to be described later) via a resistor R6. Accordingly, ON or OFF of the switch formed by the transistor N1 is determined by the output from the hysteresis comparator HC. When a low-level signal is output, the switch is turned on to make the RC filter operative. When a high-level signal is output, the switch is turned off to make the RC filter inoperative.

The resistors R6 and R7 have a resistance necessary to cut off a high-frequency signal. The function of an RC filter can be obtained if one of the resistors R4 and R5 and one of the capacitors C1 and C2 are present. However, to maintain the symmetry of the differential output signals, it is desirable to make pairs of these resistors and capacitors.

The RC filter with the switch as described above is switched on or off by an output signal from a high-frequency-signal detection circuit to be described below (i.e., the output from the hysteresis comparator HC). This high-frequency-signal detection circuit includes a high-pass filter HPF, a detection rectifier DPR, and the hysteresis comparator HC.

As load resistors of the differential output unit 1, the resistors R1 and R3 are connected in series to the differential output terminal OUT−, and the resistor R2 is connected to the output terminal OUT+.

The total resistance of the resistors R1 and R3 is equal to the resistance of the resistor R2. In addition, the resistance of the resistor R3 is set to be much smaller than, e.g., about 1/10 the total resistance of resistor R1+resistor R3.

For example, if the resistor R2 is about 50 Ω, the resistor R3 is about 5 Ω. Therefore, the voltage amplitude at the connecting point between the resistors R3 and R1 is about 1/10 the output amplitude of the output signal OUT− from the semiconductor laser driving circuit.

A signal extracted from this connecting point between the resistors R3 and R1 is input to the high-pass filter HPF. The high-pass filter HPF is desirably so designed as to function as a lossless matching circuit formed by a lossless passive element in order to convert the low-resistance resistor R3 into high impedance, in addition to having the frequency characteristics as a high-pass filter. Accordingly, the high-pass filter HPF has a voltage amplification function. Also, the output impedance of the high-pass filter HPF is set to be higher than its input impedance. Furthermore, letting A (b/s) be the basic frequency of a signal to be supplied to the laser diode LD1, the low-frequency cutoff frequency of the high-pass filter HPF must be higher than A/2 (Hz).

The high-pass filter HPF is followed by the detection rectifier DPR having a high input impedance. Since the high-pass filter HPF has the voltage amplification function, the high-pass filter HPF generates a voltage amplitude with which the detection rectifier DPR connected to the output stage of the high-pass filter HPF well functions.

As shown in FIG. 1, the detection rectifier DPR includes an emitter follower circuit formed by an NPN transistor Q4 and resistor R8, and an integrating circuit formed by a load capacitor C3, resistor R9, and capacitor C4. The output from the high-pass filter HPF is applied to the base of the transistor Q4. The load capacitor C3 is connected between the emitter of the transistor Q4 and the ground terminal.

An output signal from the detection rectifier DPR is input to the inverting input terminal of the hysteresis comparator formed after the detection rectifier DPR. This output is a control signal for controlling ON/OFF of the transistor N1 included in the RC filter circuit with the switch.

Letting Vth_H and Vth_L be the high- and low-potential threshold voltages, respectively, of the hysteresis comparator HC, the input signal potential to the hysteresis comparator HC is set between the threshold voltages Vth_H and Vth_L, if there is no high-frequency component to be removed by the RC filter with the switch.

If no high-frequency component is present, a high-level signal is output from the hysteresis comparator HC to generate a high-frequency component. This high-frequency component is converted into a DC component or low-frequency component by the integrating circuit of the detection rectifier DPR. If this level once exceeds the threshold voltage Vth_H, the hysteresis comparator HC outputs a low-level signal. The hysteresis comparator HC maintains this low-level outputs unless the level of the DC component or low-frequency component becomes lower than the threshold voltage Vth_L.

More specifically, if the presence of a high-frequency component is detected and the hysteresis comparator HC outputs a low-level signal to make the RC filter with the switch operative, the hysteresis comparator HC maintains this low-level output to keep the RC filter operative in most cases.

The operation of the semiconductor laser driving circuit according to this embodiment having the above arrangement will be explained below.

The output terminal OUT− is connected to the laser diode LD1 and its peripheral circuits as shown in FIG. 5. Therefore, the parasitic inductance or parasitic capacitance of any of these circuits generates overshoot, undershoot, or ringing in the voltage waveform of the output signal supplied from the terminal OUT−.

If the waveform thus deteriorates, a frequency component higher than the basic frequency (=A/2 Hz when the transmission rate is A bps) appears as a spectral component on the frequency axis. In this embodiment, when this high-frequency component is detected by the detection rectifier DPR, the hysteresis comparator HC outputs a low-level signal to make the RC filter operative, thereby suppressing the high-frequency component.

To achieve this operation, the high-frequency-signal detection circuit including the high-pass filter HPF which also functions as an impedance converter, the detection rectifier DPR having a high impedance input, and the hysteresis comparator HC is formed. Since the high-pass filter HPF also functions as an impedance converter, a very small voltage amplitude can be amplified to a large-amplitude signal.

Also, as described above, the input signal to the high-frequency-signal detection circuit is extracted from the connecting point between the resistors R3 and R1. Since the resistor R3 is much smaller than the resistor R1, a voltage drop produced across the resistor R3 is small. This makes waveform deterioration caused by the addition of the high-frequency-signal detection circuit negligibly small.

While no high-frequency component which causes waveform deterioration is generated at the output terminal OUT−, the level of the DC component or low-frequency component output form the integrator included in the detection rectifier DPR is low. So, the hysteresis comparator HC outputs a high-level signal, and the NMOS transistor N1 remains OFF. Since RC filter with the switch formed between the output terminals OUT− and OUT+is inoperative, the waveform does not deteriorate by any unnecessary operation of the RC filter.

Once a high-frequency component which causes waveform deterioration is generated at the output terminal OUT−, the level of the DC component or low-frequency component output from the integrator included in the detection rectifier DPR rises. If this level exceeds the high-potential threshold voltage Vth_H of the hysteresis comparator HC, the hysteresis comparator HC outputs a low-level signal to turn on the NMOS transistor N1. Consequently, the RC filter with the switch formed between the output terminals OUT− and OUT+ so functions as to remove the high-frequency component, thereby suppressing waveform deterioration.

Once the NMOS transistor N1 is turned on and the RC filter starts operating, this RC filter keeps operating unless the level of the DC component or low-frequency component from the detection rectifier DPR becomes lower than the low-potential threshold voltage Vth_L of the hysteresis comparator HC.

Accordingly, even when the RC filter starts operating once to decrease the high-frequency component by suppressing waveform deterioration and the level of the DC component or low-frequency component from the detection rectifier lowers, the output potential maintains low level unless it becomes lower than the low-potential threshold voltage Vth_L of the hysteresis comparator HC, and the RC filter keeps operating. Therefore, the RC filter does not deteriorate the waveform by frequently repeating the operative and inoperative states.

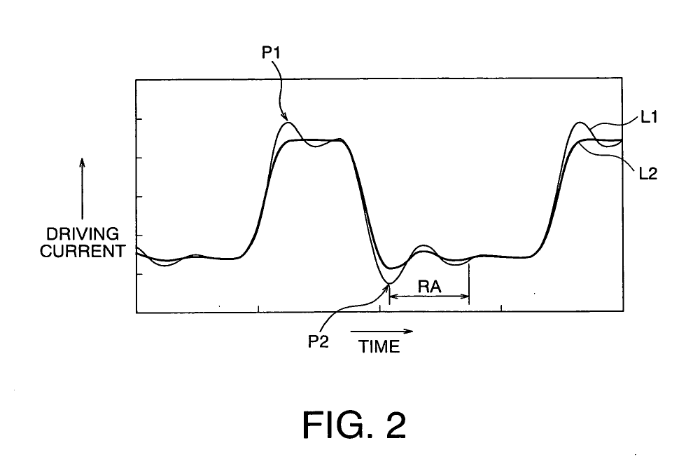

FIG. 2 is a graph comparing curves L1 and L2. The curve L1 indicates the result of simulation of the waveform of a driving current in the conventional semiconductor laser driving circuit 103 shown in FIG. 5. The curve L2 indicates the result of simulation of the waveform of a driving current in the semiconductor laser driving circuit according to the embodiment shown in FIG. 1.

Each of the curves L1 and L2 shows the waveform on the time axis of an electric current, i.e., a driving current flowing into the output terminal OUT− of the semiconductor laser driving circuit when the laser diode LD1 and its peripheral circuits such as the RC filter RCF are connected to the output terminal OUT−.

As indicated by the curve L2, in the conventional semiconductor driving circuit, overshoot occurs at a point P1, undershoot occurs at a point P2, and ringing occurs at both the points P1 and P2. In contrast, in the embodiment described above, these phenomena are greatly improved, and waveform deterioration is suppressed.

In this embodiment, therefore, even when the temperature changes, deterioration of the output waveform of the driving current can be prevented by making the RC filter circuit with the switch operative or inoperative in accordance with the temperature.

(2) Second Embodiment

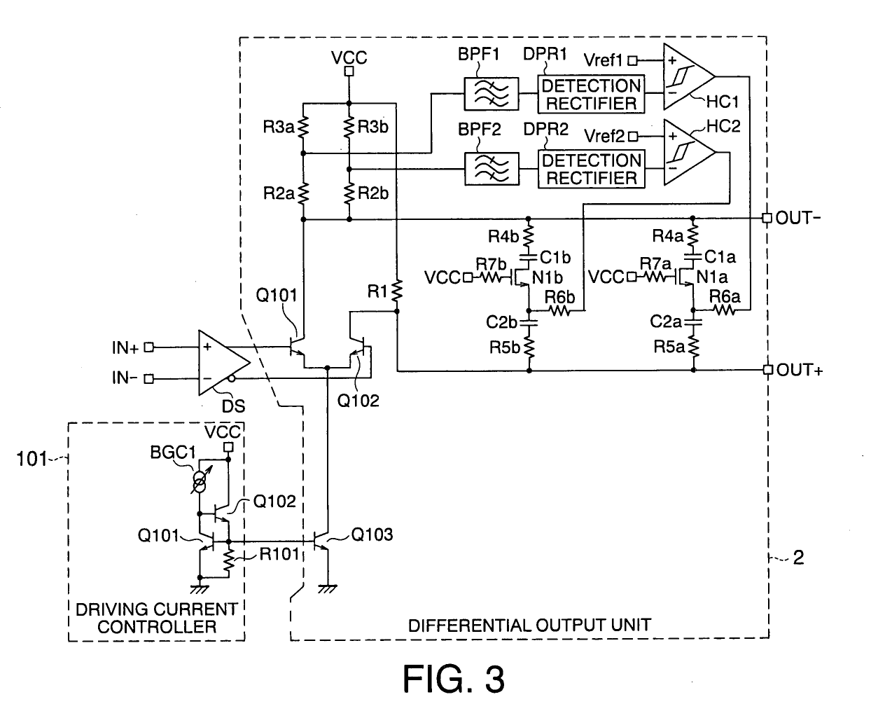

FIG. 3 shows the arrangement of a semiconductor laser driving circuit according to the second embodiment of the present invention.

This embodiment differs from the above first embodiment in that the circuit includes two systems of RC filters with switches and high-frequency-signal detection circuits.

The input terminal of a bandpass filter BPF1 is connected to one end of a load resistor R3a for detecting a high-frequency component. The input terminal of a detection rectifier DPR1 having the same arrangement as the detection rectifier DPR shown in FIG. 1 is connected to the output terminal of the bandpass filter BPF1. The inverting input terminal of a hysteresis comparator HC1 is connected to the output terminal of the detection rectifier DPR1.

Likewise, the input terminal of a bandpass filter BPF2 is connected to one end of a load resistor R3b for detecting a high-frequency component. The input terminal of a detection rectifier DPR2 having the same arrangement as the detection rectifier DPR1 is connected to the output terminal of the bandpass filter BPF2. The inverting input terminal of a hysteresis comparator HC2 is connected to the output terminal of the detection rectifier DPR1.

Between output terminals OUT− and OUT+, a resistor R4a, capacitor C1a, NMOS transistor N1a, capacitor C2a, and resistor R5a are connected in series to form one RC filter with a switch. In parallel with this RC filter with the switch, a resistor R4b, capacitor C1b, NMOS transistor N1b, capacitor C2b, and resistor R5b are connected in series to form another RC filter with a switch.

An output from the hysteresis comparator HC1 is input to the source of one RC filter with the switch via a resistor R6a. An output from the hysteresis comparator HC2 is input to the source of the other RC filter with the switch via a resistor R6b.

The resistances of the load resistors R3a and R3b for detecting a high-frequency component have the following relationship with the resistors R2a and R2b

(R3a+R2a)//(R3b+R2b)=R1 (1)

where symbol “//” represents a resistance obtained by parallel connection.

For example, R3a=R3b and R2a=R2b are also possible.

Also, as in the first embodiment described above, the resistance of R3a can be about 1/10 that of R3a+R2a, and the resistance of R3b can be about 1/10 that of R3b+R2b.

Circuit parameters of the two RC filters with the switches are set at different values as follows.

Let f1L and f1H be the low- and high-frequency cutoff frequencies, respectively, of the bandpass filter BPF1, and f2L and f2H be the low- and high-frequency cutoff frequencies, respectively, of the bandpass filter BPF2. Also, let fa be the cutoff frequency of one RC filter with the switch including the NMOS transistor Nla, and fb be the cutoff frequency of the other RC filter with the switch including the NMOS transistor Nlb. Then, these circuit parameters are set such that

fa=f1L (2)

fb=f2L (3)

f1H=f2L (4)

By thus setting the circuit parameters, even when a temperature change occurs, an optimum one of the two RC filters with the switches is selectively operated in accordance with the frequency of a high-frequency component which causes waveform deterioration. Accordingly, the definitions tr and tf concerning the leading edge and trailing edge, respectively, of a waveform and having a tradeoff relationship with suppression of waveform deterioration can be improved better than in the first embodiment.

In the semiconductor laser driving circuits of the embodiments described above, a signal is extracted from the connecting point between the two resistors connected to the first or second output terminal. A high-frequency component is extracted from this signal through the high-pass filter or bandpass filter, converted into a DC component or low-frequency component by the detection rectifier, and input to the hysteresis comparator. If this component exceeds a predetermined value, the switch is turned on to make the RC filter with the switch operative, thereby suppressing waveform deterioration. Accordingly, it is possible to avoid an event in which an RC filter is unnecessarily operated to deteriorate the waveform although no high-frequency component is contained.

Each of the above embodiments is merely an example, and hence does not limit the present invention and can be variously modified.

For example, in the first embodiment shown in FIG. 1, to control ON/OFF of the NMOS transistor N1 which operates as a switch, the output terminal of the hysteresis comparator HC is connected to the source of the transistor N1, so that the transistor N1 is turned on when the output from the hysteresis comparator HC is at low level.

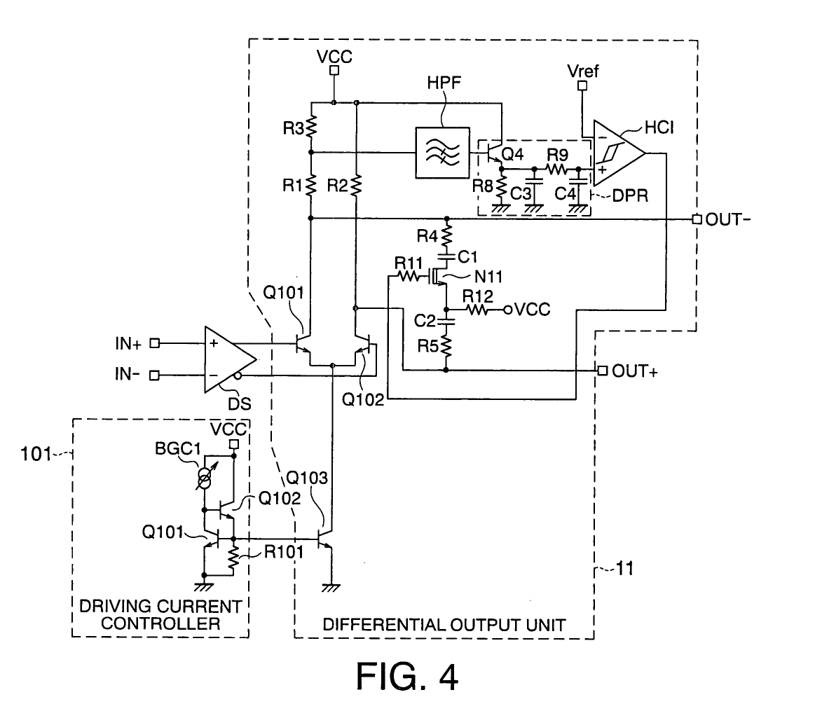

As shown in FIG. 4, however, it is also possible to supply an appropriate bias potential (e.g., VCC) to the source of, e.g., a depression type MOS transistor N1l via a resistor R12, and input an output from a hysteresis comparator HC1 as a control signal to the gate of the transistor N1l via a resistor R11.

In this case, however the polarities of the hysteresis comparator HC1 must be set to be opposite to those of the first embodiment. That is, it is necessary to input a reference potential Vref to the inverting input terminal, and an output from a detection rectifier DPR to the non-inverting input terminal.

In the above embodiments, bipolar transistors are used as the transistors Q101 and Q102 of the differential output unit. However, it is also possible to use various FETs, e.g., MESFETs, HEMTs, and MOSFETs.

The transistor as a switch of the RC filter with the switch is not limited to an NMOS transistor, and may also be a PMOS transistor or any of the above-mentioned various FETs. In this case, however, the polarities must be so that that the RC filter operates in response to the output from the high-pass filter when a high-frequency component is detected.

In addition, instead of the high-pass filter HPF used in the first embodiment, a bandpass filter having a sufficiently high high-frequency cutoff frequency can be used.

Furthermore, the second embodiment uses the two systems of the RC filters with the switches and the high-frequency-signal detection circuits. However, three or more systems may also be formed by using the same method. In this case, more precise waveform deterioration suppression is possible.

What is claimed is:

1. A semiconductor laser driving circuit including a differential output unit which performs differential amplification by receiving complementary input signals, and outputs complementary signals from first and second output terminals, comprising:
an RC filter with a switch obtained by connecting, between said first and second output terminals, two ends of a switching element, two ends of at least one resistor, and two ends of at least one capacitor in series;
two resistors connected in series between a high-potential power supply terminal and said first output terminal;
a high-pass filter or bandpass filter which receives an output from a connecting point between said two resistors, and passes a component not lower than a predetermined frequency;
a detection rectifier which receives a signal passed through said high-pass filter or bandpass filter, converts the received signal into a DC component or low-frequency component, and outputs the DC component or low-frequency component; and
a hysteresis comparator which receives an output from said detection rectifier, outputs an ON signal if the received output exceeds a high-potential threshold value, and keeps outputting the ON signal unless the output from said detection rectifier becomes lower than a low-potential threshold value,
wherein said switching element is turned on and said RC filter with said switch starts operating accordingly when the output ON signal from said hysteresis comparator is supplied to said switching element.

2. A circuit according to claim 1, wherein said high-pass filter or bandpass filter comprises a lossless passive element, an output impedance is higher than an input impedance, and, letting A (b/s) be a base frequency of the output signals from said first and second output terminals, a low-frequency cutoff frequency is higher than A/2 (Hz).

3. A circuit according to claim 2, wherein said detection rectifier has an emitter follower circuit including a capacitive load.

4. An optical communication apparatus comprising:
a semiconductor laser driving circuit cited in claim 2; and
a laser diode which receives an output signal from a first or second output terminal of said semiconductor laser driving circuit.

5. A circuit according to claim 1, wherein said detection rectifier has an emitter follower circuit including a capacitive load.

6. An optical communication apparatus comprising:
a semiconductor laser driving circuit cited in claim 1; and
a laser diode which receives an output signal from a first or second output terminal of said semiconductor laser driving circuit.

7. A semiconductor laser driving circuit including a differential output unit which performs differential amplification by receiving complementary input signals, and outputs complementary signals from first and second output terminals, comprising:
first, second, . . . , nth (n is an integer not less than 2) RC filters with switches each of which is obtained by connecting, between said first and second output terminals, two ends of a switching element, two ends of at least one resistor, and two ends of at least one capacitor in series, and which are connected to each other in parallel;
first, second, . . . , nth resistor units each of which includes two resistors connected in series between a high-potential power supply terminal and said first output terminal, and which are connected to each other in parallel;
first, second, . . . , nth bandpass filters each of which receives an output from a connecting point between said two resistors included in a corresponding one of said first, second, . . . , nth resistor units, and passes a component not lower than a predetermined frequency;
first, second, . . . , nth detection rectifiers each of which receives a signal passed through a corresponding one of said first, second, . . . , nth bandpass filters, converts the received signal into a DC component or low-frequency component, and outputs the DC component or low-frequency-component; and
first, second, . . . , nth hysteresis comparators each of which receives an output from a corresponding one of said first, second, . . . , nth detection rectifiers, outputs an ON signal if the received output exceeds a high-potential threshold value, and keeps outputting the ON signal unless the output from said detection rectifier becomes lower than a low-potential threshold value,
wherein said switching element included in each of said first, second, . . . , nth RC filters with said switches is turned on when the output ON signal from a corresponding one of said first, second, . . . , nth hysteresis comparators is supplied, and a corresponding one of said first, second, . . . , nth RC filters with said switches starts operating accordingly.

8. A circuit according to claim 7, wherein each of said first, second, . . . , nth bandpass filters comprises a lossless passive element, an output impedance is higher than an input impedance, and, letting A (b/s) be a basic frequency of the output signals from said first and second output terminals, a low-frequency cutoff frequency is higher than A/2 (Hz).

9. A circuit according to claim 8, wherein each of said first, second, . . . , nth detection rectifiers has an emitter follower circuit including a capacitive load.

10. An optical communication apparatus comprising:
a semiconductor laser driving circuit cited in claim 8; and
a laser diode which receives an output signal from a first or second output terminal of said semiconductor laser driving circuit.

11. A circuit according to claim 7, wherein said detection rectifier has an emitter follower circuit including a capacitive load.

12. An optical communication apparatus comprising:
a semiconductor laser driving circuit cited in claim 7; and
a laser diode which receives an output signal from a first or second output terminal of said semiconductor laser driving circuit.
